(19) United States
(12) Patent Application Publication
(10) Pub. No.: US 2023/0207013 A1
(43) Pub. Date: Jun. 29, 2023

(54) MEMORY DEVICE INCLUDING ROW DECODER

(71) Applicant: SK hynix Inc., Icheon-si (KR)

(72) Inventors: Sang Hyun SUNG, Icheon-si (KR); Sung Lae OH, Icheon-si (KR)

(21) Appl. No.: 17/725,372

(22) Filed: Apr. 20, 2022

(30) Foreign Application Priority Data
Dec. 23, 2021 (KR) 10-2021-0186321

(51) Int. Cl. G11C 16/08; G11C 16/24

(52) U.S. Cl. CPC G11C 16/08; G11C 16/24

(57) ABSTRACT

A memory device includes a memory cell array included in a first semiconductor layer, and including a plurality of row lines that extend in a first direction, each of the plurality of row lines having a pad part disposed in a slimming region; a row decoder included in a second semiconductor layer disposed under the first semiconductor layer, and overlapping the memory cell array in a vertical direction; slimming regions disposed on both sides of the row decoder in the first direction; and a plurality of wiring lines coupling the pad parts of the plurality of row lines and the row decoder.

### CROSS-REFERENCE TO RELATED APPLICATION

The present application claims priority under 35 U.S.C. § 119(a) to Korean Patent Application No. 10-2021-0186321 filed in the Korean Intellectual Property Office on Dec. 23, 2021, which is incorporated herein by reference in its entirety.

### BACKGROUND

### 1. Technical Field

Various embodiments generally relate to a semiconductor technology, and more particularly, to a memory device that includes a row decoder.

### 2. Related Art

A memory device with a two-dimensional or planar structure has been developed to store more data in the same area by using fine is patterning processes. However, as the line width of a circuit is narrowed due to the demand for high integration, the interference between memory cells becomes critical, which can result in various limitations such as degradation in performance. Of course, in addition to such structural limitations, there is a problem in that an increase in manufacturing cost is inevitable because the introduction of expensive equipment is required to pattern a fine line width.

As an alternative to overcome limitations of two-dimensional memory devices, a three-dimensional memory device has been proposed. A three-dimensional memory device has advantages in that a larger capacity may be realized within the same area by increasing the number of stacks through stacking memory cells in a vertical direction, thereby providing high performance and excellent power efficiency.

In a three-dimensional memory device, the degree of integration may be increased by increasing the number of electrode layers, specifically word lines, to be stacked. However, if the number of electrode layers in the stack is increases, the number of pass transistors increases, and thus, the size of a row decoder also increases. As the number of wiring lines that couple the row decoder and the electrode layers increases, the area consumed for the layout of the wiring lines increases, and thus, the size or area of the memory device may increase.

### SUMMARY

Various embodiments are directed to a memory device having a reduced size or area.

In an embodiment, a memory device may include: a memory cell array included in a first semiconductor layer, and including a plurality of row lines that extend in a first direction, each of the plurality of row lines having a pad part disposed in a slimming region; a row decoder included in a second semiconductor layer disposed under the first semiconductor layer, and overlapping the memory cell array in a vertical direction; slimming regions disposed on both sides of the row decoder in the first direction; and a plurality of wiring lines coupling the pad parts of the plurality of row lines and the row decoder.

In an embodiment, a memory device may include: a memory cell array including a plurality of interlayer dielectric layers and a plurality of electrode layers that are alternately stacked on a source plate; a row decoder disposed on a substrate disposed under the source plate, and overlapping the memory cell array in a vertical direction; and a plurality of wiring lines, configured in a bottom wiring layer between the substrate and the source plate, that couple pad parts of the plurality of electrode layers and the row decoder, wherein when viewed from the top, some of the plurality of wiring lines are disposed in one side of the row decoder, and the other of the plurality of wiring lines are disposed in the other side of the row decoder.

### BRIEF DESCRIPTION OF THE DRAWINGS

FIG. 1 is a block diagram of a memory device in accordance with an embodiment of the present disclosure.

FIG. 2 is a perspective view schematically illustrating a memory device in accordance with an embodiment of the present disclosure.

FIG. 3 is a schematic top view illustrating the memory device.

FIG. 4 is a view illustrating a memory device in accordance with an embodiment of the present disclosure.

FIG. 5 is a top view illustrating routing directions of wiring lines that couple slimming regions and row decoder regions of the memory device in accordance with the embodiment of the present disclosure.

FIG. 6 is a top view illustrating a memory device that is different from embodiments of the present disclosure.

FIGS. 7 and 8 are diagrams illustrating problems of a memory device that is different from the embodiments of present disclosure.

FIG. 9 is a block diagram schematically illustrating a memory system including a memory device in accordance with an embodiment of the present disclosure.

FIG. 10 is a block diagram schematically illustrating a computing system including a memory device in accordance with an embodiment of the present disclosure.

### DETAILED DESCRIPTION

Advantages and features of the disclosure and methods to achieve them will become apparent from the descriptions of exemplary embodiments herein below and described with reference to the accompanying drawings. However, the present disclosure is not limited to the exemplary embodiments disclosed herein but may be implemented in various different ways. The exemplary embodiments of the present disclosure convey the scope of the disclosure to those skilled in the art.

The figures, dimensions, ratios, angles, numbers of elements given in the drawings that describe embodiments of the disclosure are merely illustrative and are not limiting. Throughout the specification, like reference numerals refer to like elements. In describing the disclosure, when it is determined that a detailed description of the known related art may obscure the gist or clarity of the disclosure, the detailed description thereof will be omitted. It is to be understood that the terms “comprising,” “having,” “including” and so on, used in the description and claims, should not be interpreted as being restricted to the means listed thereafter unless specifically stated otherwise. Where an indefinite or definite article is used when referring to a singular noun (e.g. “a,” “an,” “the”), the article may include a plural of that noun unless specifically stated otherwise.

In interpreting elements in embodiments of the disclosure, they should be interpreted as including error margins even in the absence of explicit statements.

Also, in describing the components of the disclosure, there may be terms used like first, second, A, B, (a), and (b). These are solely for the purpose of differentiating one component from the other and do not to imply or suggest the substances, order, sequence or number of the components. Also, elements in embodiments of the disclosure are not limited by these terms. These terms are used to merely distinguish one element from another. Accordingly, as used herein, a first element may be a second element within the technical idea of the disclosure.

If a component is described as “connected,” “coupled” or “linked” to another component, it may mean that the component is not only directly “connected,” “coupled” or “linked” but also is indirectly “connected,” “coupled” or “linked” via a third component. In describing positional relationship, such as “an element A on an element B,” “an element A above an element B,” “an element A below an element B” and “an element A next to an element B,” another element C may be disposed between the elements A and B unless the term “directly” or “immediately” is explicitly used.

Features of various exemplary embodiments of the disclosure may be coupled, combined or separated partially or totally. Technically various interactions and operations are possible. Various exemplary embodiments can be practiced individually or in combination.

Hereinafter, various examples of embodiments of the disclosure will be described in detail with reference to the accompanying drawings.

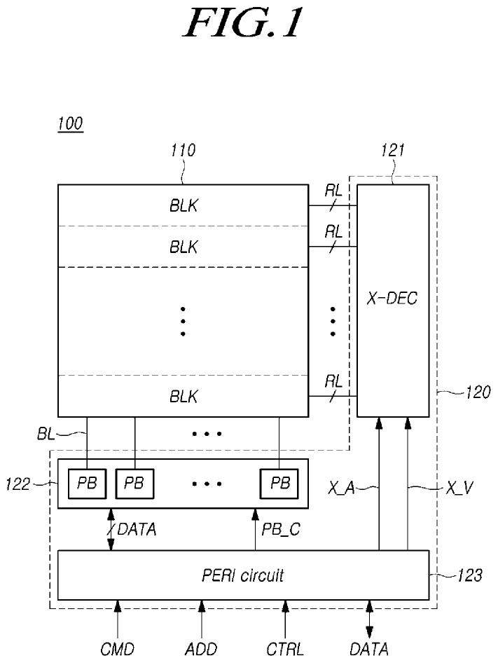

FIG. 1 is a block diagram schematically illustrating a memory device in accordance with an embodiment of the present disclosure.

Referring to FIG. 1, a memory device 100 in accordance with the embodiment of the disclosure may include a memory cell array 110 and a logic circuit 120. The logic circuit 120 may include a row decoder (X-DEC) 121, a page buffer circuit 122 and a peripheral circuit (PERI circuit) 123.

The memory cell array 110 may be coupled to the row decoder 121 through a plurality of row lines RL, and may be coupled to the page buffer circuit 122 through a plurality of bit lines BL. The row lines RL may include drain select lines, word lines and source select lines.

The memory cell array 110 may include a plurality of memory cells, which are disposed in regions where the plurality of bit lines BL and the plurality of word lines intersect. The memory cell may be a volatile memory cell, which loses data stored therein when power supply is cut off, or the memory cell may be a nonvolatile memory cell, which retains data stored therein even when power supply is cut off. For example, when the memory cell is a volatile memory cell, the memory device 100 may be a DRAM (dynamic random access memory), an SRAM (static random access memory), a mobile DRAM, a DDR SDRAM (double data rate synchronous dynamic random access memory), an LPDDR (low power DDR) SDRAM, a GDDR (graphic DDR) SDRAM or an RDRAM (Rambus dynamic random access memory). When the memory cell is a nonvolatile memory cell, the memory device 100 may be an EEPROM (electrically erasable programmable read-only memory), a flash memory, a PRAM (phase change random access memory), an RRAM (resistive random access memory), an NFGM (nano-floating gate memory), a PoRAM (polymer random access memory), an MRAM (magnetic random access memory) or an FRAM (ferroelectric random access memory), as examples. The memory device 100 may be a hybrid memory, which includes both volatile memory cells and nonvolatile memory cells.

The memory cell may be a single level cell (SLC), which stores one-bit data, or a multi-level cell (MLC), which stores two or more-bit data. A multi-level cell may store two-bit data, three-bit data, four-bit data, and so forth. The memory cell array 110 may include at least one of a single level cells and a multi-level cell.

The memory cell array 110 may include a plurality of memory blocks BLK. Although not illustrated, each memory block BLK may include a plurality of pages. The memory block BLK may be a basic unit of an erase operation, and the page may be a basic unit of a read operation.

The row decoder 121 may select a memory block BLK in response to a row address X_A from the peripheral circuit 123, and may transfer an operating voltage X_V from the peripheral circuit 123 to row lines RL of the selected memory block BLK. The row decoder 121 may include a pass transistor circuit and a block switch circuit. The pass transistor circuit may include a plurality of pass transistors. Each pass transistor may transfer the operating voltage X_V to a corresponding row line RL in response to a block selection signal from the block switch circuit. The block switch circuit may generate the block selection signal for selecting one of the plurality of memory blocks BLK in response to the row address X_A. Some of the pass transistors may be turned on in response to the block selection signal, and the operating voltage X_V may be transferred to the row lines RL of the selected memory block BLK through the turned-on pass transistors.

The page buffer circuit 122 may include a plurality of page buffers PB, which are coupled to the plurality of bit lines BL, respectively. A page buffer PB may receive a page buffer control signal PB_C from the peripheral circuit 123, and may transmit and receive a data signal DATA to and from the peripheral circuit 123. The page buffer PB may control a bit line BL in response to the page buffer control signal PB_C. For example, the page buffer PB may detect data, stored in a memory cell of the memory cell array 110, by sensing the signal of a bit line BL of the memory cell array 110 in response to the page buffer control signal PB_C, and may transmit the data signal DATA to the peripheral circuit 123 according to the detected data. The page buffer PB may apply a signal to the bit line BL, based on the data signal DATA received from the peripheral circuit 123, in response to the page buffer control signal PB_C, and accordingly, may write data to a memory cell of the memory cell array 110. The page buffer PB may write or read data to or from a memory cell that is coupled to an activated word line.

The peripheral circuit 123 may receive a command signal CMD, an address signal ADD and a control signal CTRL from outside the memory device 100, and may transmit and receive data DATA to and from a device outside the memory device 100, such as, a memory controller. The peripheral circuit 123 may output signals for writing data to the memory cell array 110 or reading data from the memory cell array 110, for example, the row address X_A, the page buffer control signal PB_C and so forth, based on the command signal CMD, the address signal ADD and the control signal CTRL. The peripheral circuit 123 may generate various voltages including the operating voltage X_V, which are required in the memory device 100.

Hereinbelow, in the accompanying drawings, a direction vertically projecting from the top surface of a substrate is defined as a vertical direction VD, and two directions parallel to the top surface of the substrate and intersecting with each other are defined as a first direction FD and a second direction SD, respectively. For example, the first direction FD may be the extending direction of row lines and the arrangement direction of bit lines, and the second direction SD may be the extending direction of the bit lines and the arrangement direction of the row lines. The first direction FD and the second direction SD may substantially perpendicularly intersect with each other. In the drawings, a direction indicated by an arrow and a direction opposite thereto indicate the same direction.

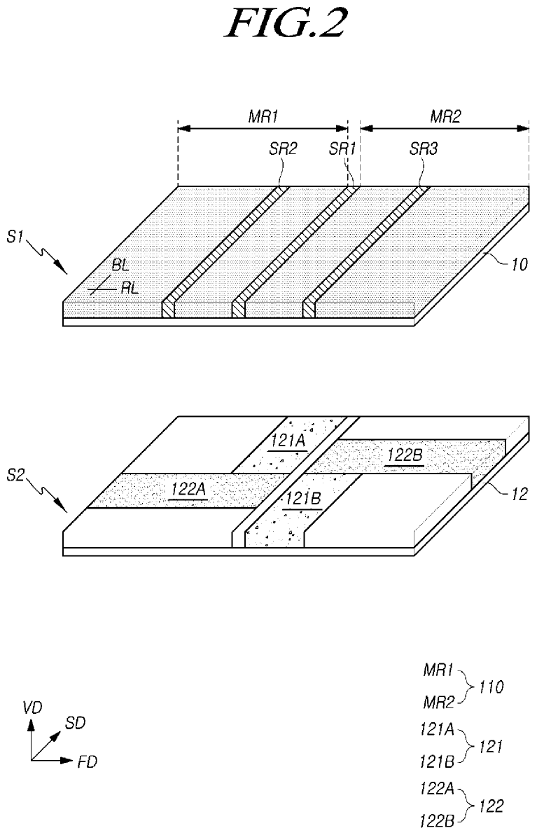

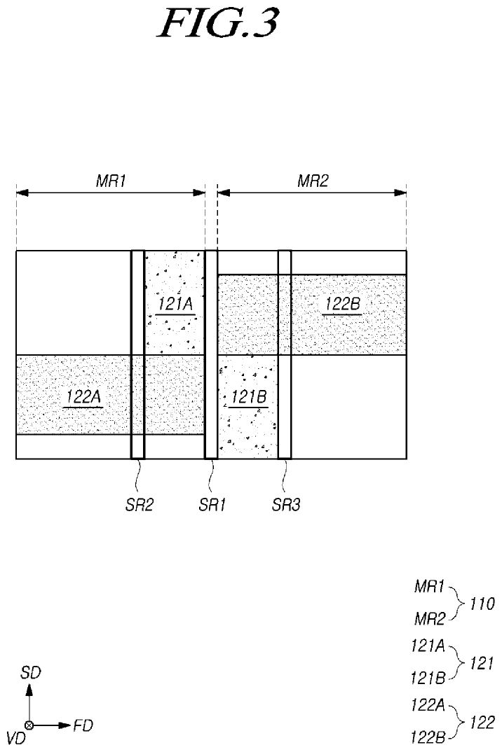

FIG. 2 is a perspective view schematically illustrating a memory device in accordance with an embodiment of the present disclosure, and FIG. 3 is a schematic top view illustrating the memory device.

Referring to FIGS. 2 and 3, a memory device in accordance with an embodiment of the present disclosure may include a first semiconductor layer S1 that includes a memory cell array 110 and a plurality of row lines RL that extend in the first direction FD; a second semiconductor layer S2 including a row decoder 121; and a plurality of wiring lines (not illustrated) that couple pad parts (not illustrated) to the plurality of row lines RL. The second semiconductor layer S2 is disposed under the first semiconductor layer S1 and overlaps the memory cell array 110 in the vertical direction VD. Referring to FIG. 3, the portion of each of the plurality of row lines that is coupled to the plurality of wiring lines and pad parts are configured or disposed in slimming regions SR1, SR2 and SR3, which are positioned on both sides of the row decoder 121 in the first direction FD, and between a first row decoder region 121A and a second row decoder region 121B.

In detail, the first semiconductor layer S1 may include a source plate 10 and the memory cell array 110, which is disposed on the source plate 10. The memory cell array 110 may be divided into a first memory region MR1 and a second memory region MR2, and the first memory region MR1 and the second memory region MR2 may be disposed to be adjacent to each other in the first direction FD.

The memory cell array 110 may include the plurality of row lines RL, a plurality of bit lines BL, and a plurality of memory cells that are coupled to the plurality of row lines RL and the plurality of bit lines BL.

Although not illustrated in detail, each of the row lines RL may traverse the first memory region MR1 and the second memory region MR2 in the first direction FD. The first memory region MR1 and the second memory region MR2 may be coupled in common to the row lines RL, and may share the row lines RL. The bit lines BL may be divided into two bit line groups that are included in the first memory region MR1 and the second memory region MR2, respectively.

Each row line RL may include a pad part, which may be an electrical contact for coupling the row line RL to the row decoder 121. The pad parts of the row lines RL may be distributedly disposed in the slimming regions SR1, SR2 and SR3. The slimming regions SR1, SR2 and SR3 may be arranged in the first direction FD, and may be configured to each have a line or bar shape that extends in the second direction SD, which is a direction in which the row lines RL are arranged.

The slimming regions SR1, SR2 and SR3 may be described as a first slimming region SR1, a second slimming region SR2 and a third slimming region SR3. The first slimming region SR1 may be configured or disposed between the first memory region MR1 and the second memory region MR2. The first memory region MR1 and the second memory region MR2 may be disposed on both sides, respectively, of the first slimming region SR1 in the first direction FD. The second slimming region SR2 may be configured or disposed in the first memory region MR1. The third slimming region SR3 may be configured or disposed in the second memory region MR2.

The second semiconductor layer S2 may include a substrate 12, the row decoder 121 and a page buffer circuit 122. The row decoder 121 and the page buffer circuit 122 may be configured or disposed on the substrate 12. In order to increase the overlap area with the memory cell array 110, the row decoder 121 and the page buffer circuit 122 may each be divided into two regions. From a layout view, the regions of the row decoder 121 and the page buffer circuit 122 have the shape of windmill vanes as illustrated in FIGS. 2 and 3. Such a structure may define a tile structure.

Hereinafter, for the sake of convenience in explanation, two row decoder regions that configure the row decoder 121 are defined as a first row decoder region 121A and a second row decoder region 121B, and two page buffer regions that configure the page buffer circuit 122 are defined as a first page buffer region 122A and a second page buffer region 122B.

The first row decoder region 121A and the first page buffer region 122A may be disposed in a region that overlaps with the first memory region MR1 in the vertical direction VD. The second row decoder region 121B and the second page buffer region 122B may be disposed in a region that overlaps with the second memory region MR2 in the vertical direction VD.

When viewed from the top, the first slimming region SR1 and the second slimming region SR2 may be disposed on both sides, respectively, of the first row decoder region 121A in the first direction FD. When viewed from the top, the first row decoder region 121A may be disposed between the first slimming region SR1 and the second slimming region SR2. The first row decoder region 121A may not overlap with the first slimming region SR1 and the second slimming region SR2 in the vertical direction VD.

When viewed from the top, the first slimming region SR1 and the third slimming region SR3 may be disposed on both sides, respectively, of the second row decoder region 121B in the first direction FD. When viewed from the top, the second row decoder region 121B may be disposed between the first slimming region SR1 and the third slimming region SR3. The second row decoder region 121B may not overlap with the first slimming region SR1 and the third slimming region SR3 in the vertical direction VD.

The first page buffer region 122A and the second page buffer region 122B may be disposed on both sides, respectively, of the first slimming region SR1 in the first direction FD. The first page buffer region 122A may be configured such that the length of the first page buffer region 122A in the first direction FD, a direction in which the bit lines BL are arranged, is substantially the same as the length of the first memory region MR1 in the first direction FD. The second slimming region SR2 may intersect with the first page buffer region 122A when viewed from the top. At a portion where the second slimming region SR2 and the first page buffer region 122A intersect, the second slimming region SR2 may overlap with the first page buffer region 122A in the vertical direction VD. The second page buffer region 122B may be configured such that the length of the second page buffer region 122B in the first direction FD, the direction in which the bit lines BL are arranged, is substantially the same as the length of the second memory region MR2 in the first direction FD. The third slimming region SR3 may intersect with the second page buffer region 122B when viewed from the top. At a portion where the third slimming region SR3 and the second page buffer region 122B intersect, the third slimming region SR3 may overlap with the second page buffer region 122B in the vertical direction VD.

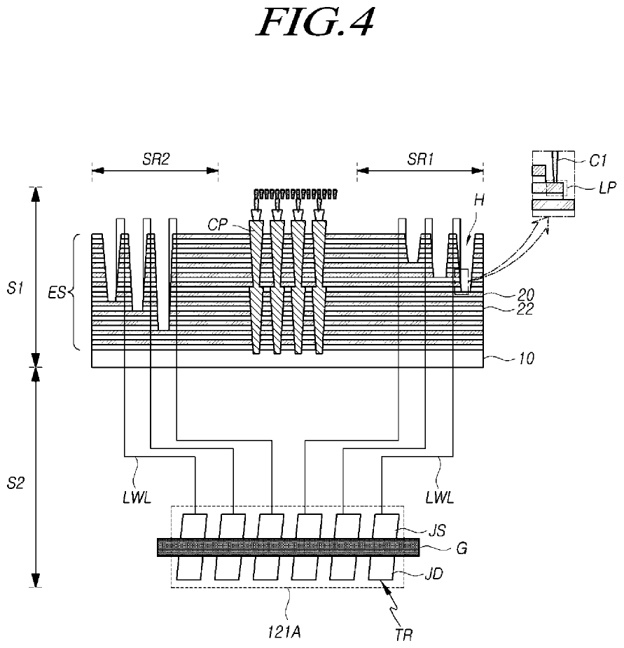

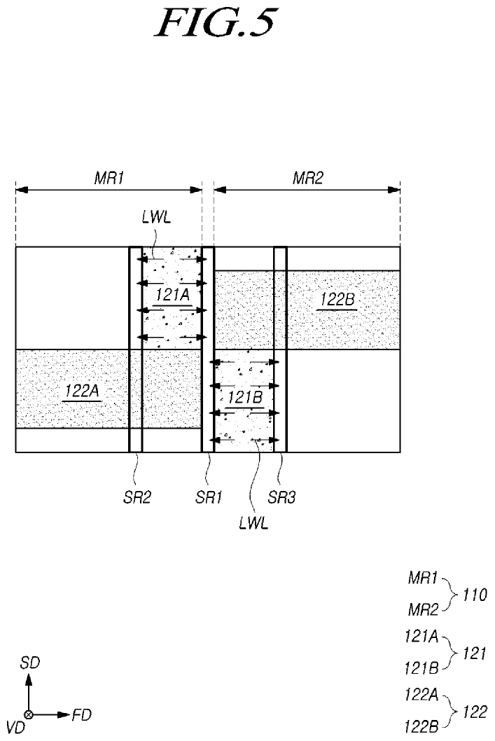

FIG. 4 is a view illustrating a memory device in accordance with an embodiment of the present disclosure, and FIG. 5 is a top view illustrating routing directions of wiring lines that couple slimming regions and row decoder regions of the memory device in accordance with the embodiment of the present disclosure.

Referring to FIG. 4, a first semiconductor layer S1 may include an electrode structure ES, which includes a plurality of electrode layers 20 and a plurality of interlayer dielectric layers 22 that are alternately stacked on the source plate 10.

For example, the source plate 10 may include at least one among silicon (Si), germanium (Ge), silicon germanium (SiGe), gallium arsenide (GaAs), indium gallium arsenide (InGaAs), aluminum gallium arsenide (AlGaAs) and a compound thereof. The source plate 10 may be a bulk silicon substrate, a silicon on insulator (SOI) substrate, a germanium substrate, a germanium on insulator (GOI) substrate, a silicon germanium substrate, or a substrate of an epitaxial thin film obtained by performing selective epitaxial growth (SEG).

The electrode layers 20 may include at least one selected from among a doped semiconductor (e.g., doped silicon), a metal (e.g., tungsten, copper or aluminum), a conductive metal nitride (e.g., titanium nitride or tantalum nitride) and a transition metal (e.g., titanium or tantalum). The interlayer dielectric layers 22 may include silicon oxide.

The electrode layers 20 may configure the row lines RL. In detail, among the electrode layers 20, at least one electrode layer 20 from the lowermost electrode layer 20 may configure a source select line. Among the electrode layers 20, at least one electrode layer 20 from the uppermost electrode layer 20 may configure a drain select line. The electrode layers 20 between the source select line and the drain select line may configure word lines.

The row decoder 121 may be configured in the second semiconductor layer S2, which lies under the first semiconductor layer S1 in the vertical direction VD. FIG. 4 illustrates only the first row decoder region 121A of the row decoder 121. It should be understood that the description of the first row decoder region 121A, which will be made below with reference to FIG. 4, can also be applied in the same or similar manner to the second row decoder region 121B (see FIG. 3).

The first row decoder region 121A may include a plurality of pass transistors TR. A pass transistor TR may include a gate line G and junction regions JD and JS, which are formed by implanting an impurity ion into the active region of a substrate on both sides of the gate line G.

A plurality of slimming holes H, which expose pad parts LP of the electrode layers 20, may be formed in the first slimming region SR1 and the second slimming region SR2 of the electrode structure ES. A contact C1 may be coupled to the pad part LP of the electrode layer 20. The pad part LP of the electrode layer 20, as a part for landing the contact C1, may protrude more in a horizontal direction than another electrode layer 20 positioned thereon.

A step structure may be configured as the pad parts LP of the electrode layers 20 are disposed in a step-like shape in each slimming hole H. Although not illustrated, each of the slimming holes H may be configured to have a width smaller than the width of the electrode structure ES so that the slimming holes H do not cut the electrode layers 20 of the electrode structure ES.

A plurality of cell plugs CP may pass through the plurality of electrode layers 20 and the plurality of interlayer dielectric layers 22 in the vertical direction VD to extend to the source plate 10. Each cell plug CP may include a channel layer and a gate dielectric layer. The channel layer may include polysilicon or monocrystalline silicon, and may include, in some regions thereof, a p-type impurity such as boron (B). The gate dielectric layer may have a shape that surrounds the outer wall of the channel layer. The gate dielectric layer may include a tunnel dielectric layer, a charge storage layer and a blocking layer, which are sequentially stacked from the outer wall of the channel layer. In some embodiments, the gate dielectric layer may have an ONO (oxide-nitride-oxide) stack structure in which an oxide layer, a nitride layer and an oxide layer are sequentially stacked. A source select transistor may be configured in regions or areas where the source select line surrounds the cell plug CP. Memory cells may be configured in regions or areas where the word lines surround the cell plug CP. A drain select transistor may be configured in regions or areas where the drain select line surrounds the cell plug CP. The source select transistor, the memory cells and the drain select transistor that are disposed along one cell plug CP may configure one cell string.

As described above with reference to FIGS. 2 and 3, when viewed from the top, the first slimming region SR1 and the second slimming region SR2 may be disposed on both sides, respectively, of the first row decoder region 121A. The plurality of cell plugs CP may be arrayed between the first slimming region SR1 and the second slimming region SR2. The first row decoder region 121A may overlap the plurality of cell plugs CP in the vertical direction VD.

Although not illustrated in detail, the second semiconductor layer S2 may include a bottom wiring layer that is disposed between the substrate 12 (see FIG. 2) and the source plate 10. A plurality of wiring lines LWL that couple the pad parts LP of the electrode layers 20 and the first row decoder region 121A may be configured in the bottom wiring layer.

The first row decoder region 121A may be coupled to the pad parts LP of the first slimming region SR1 and the pad parts LP of the second slimming region SR2 through the wiring lines LWL. In a plan view, some of the plurality of wiring lines LWL, which are coupled to the first row decoder region 121A, may extend to one side (for example to the left side in FIG. 5) of the first row decoder region 121A toward the second slimming region SR2, and some may extend to the other side (for example to the right side in FIG. 5) of the first row decoder region 121A toward the first slimming region SR1. That is to say, some of the plurality of wiring lines LWL that are coupled to the first row decoder region 121A may be disposed on the one side (the left side in the drawing) of the first row decoder region 121A, and the other some may be disposed on the other side (the right side in the drawing) of the first row decoder region 121A.

Referring to FIG. 4 and FIG. 5, the second row decoder region 121B may be coupled to the pad parts LP of the first slimming region SR1 and the pad parts LP of the third slimming region SR3 through the wiring lines LWL. The wiring lines LWL that couple the second row decoder region 121B and the first and third slimming regions SR1 and SR3 may be disposed in a wiring layer between the substrate 12 (see FIG. 2) and the source plate 10 (see FIG. 2).

In a layout view or top view, some of the plurality of wiring lines LWL that are coupled to the second row decoder region 121B may extend to one side (for example towards the left side in FIG. 5) of the second row decoder region 121B toward the first slimming region SR1, and some may extend to the other side (for example towards the right side in FIG. 5) of the second row decoder region 121B toward the third slimming region SR3. That is to say, some of the plurality of wiring lines LWL that are coupled to the second row decoder region 121B may be disposed on the one side (the left side in the drawing) of the second row decoder region 121B, and the other some may be disposed on the other side (the right side in the drawing) of the second row decoder region 121B.

Referring to FIG. 5, the wiring lines LWL that are coupled to the row decoder 121 are distributedly disposed on both sides of the first row decoder region 121A and both sides of the second row decoder region 121B. As a result, the individual wiring line LWL may be configured to have a short length that couples a row decoder region and a slimming region, which are adjacent to each other. Further, since the wiring lines LWL may be distributedly disposed in four sections arranged along the first direction FD as shown in FIG. 5, the number of wiring lines LWL disposed between the slimming region and the row decoder region which are adjacent to each other may be reduced to a maximum of one-quarter (25%) of the total number of wiring lines that couple the electrode layers 20 and the row decoder 121.

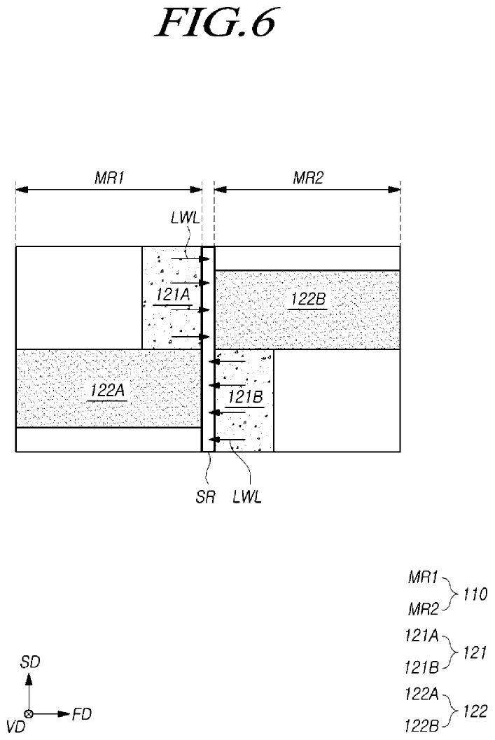

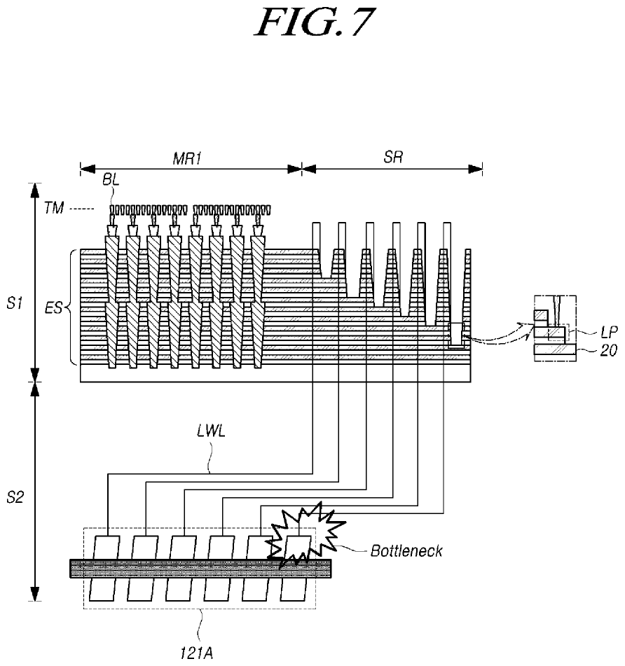

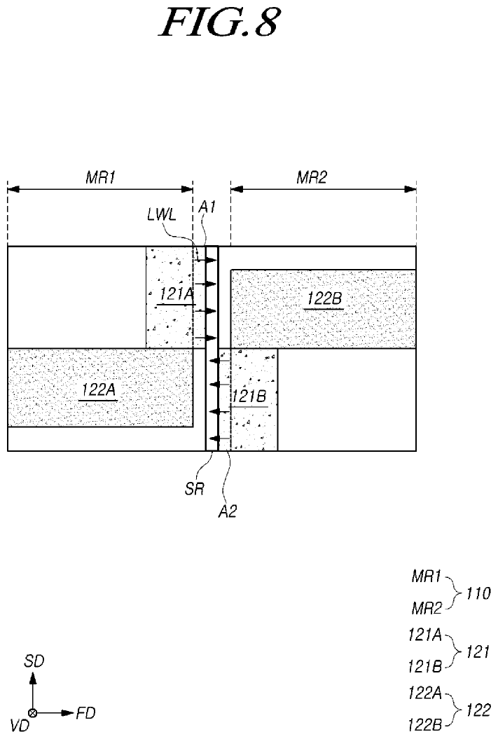

FIG. 6 is a top view illustrating a memory device that is different from the embodiments of present disclosure, and FIGS. 7 and 8 are diagrams illustrating problems of a memory device that is different from embodiments of the present disclosure.

Referring to FIGS. 6 and 7, only one slimming region SR is disposed between a first row decoder region 121A and a second row decoder region 121B. In this case, all wiring lines LWL that couple the first row decoder region 121A and the slimming region SR are routed only in a direction to the right when viewed from the first row decoder region 121A, and all wiring lines LWL that couple the second row decoder region 121B and the slimming region SR are routed only in a direction to the left when viewed from the second row decoder region 121B.

In this way, when all wiring lines LWL that are coupled to a first row decoder region 121A and a second row decoder region 121B are routed respectively in the same direction, the number of wiring lines LWL that are to be disposed common to the slimming region SR increases excessively, which results in a wiring line bottleneck phenomenon.

To solve the wiring line bottleneck phenomenon, a method of configuring some of wiring lines in a top wiring layer TM over an electrode structure ES could relieve some of the congestion. However, as illustrated in FIG. 7, since bit lines BL are arrayed in a first memory region MR1 of the top wiring layer TM, it would be too crowded to dispose wiring lines LWL in the first memory region MR1, and thus, the wiring lines LWL would need to be configured outside the first memory region MR1. Although not illustrated, because bit lines BL are arrayed also in a second memory region MR2 of the top wiring layer TM, wiring lines LWL must also be configured outside the second memory region MR2.

If the wiring lines LWL are configured outside both first and second memory regions MR1 and MR2, then in order to couple the first and second row decoder regions 121A and 121B to the wiring lines LWL, portions of the first and second row decoder regions 121A and 1218 would have to protrude to the outside the boundaries of the first and second memory regions MR1 and MR2 where the wiring lines LWL are positioned, as seen in FIG. 8. Therefore, the size of the memory device increases due to protruding portions of the first and second row decoder regions 121A and 1218. For example, A1 of FIG. 8 illustrates a protruding portion of the first row decoder region 121A, and A2 of FIG. 8 illustrates a protruding portion of the second row decoder region 121B. It may be seen that the width of the memory device in the first direction FD increases by a size corresponding to the sum of the width of the portion A1 in the first direction FD and the width of the portion A2 in the first direction FD.

As another method for solving the bottleneck phenomenon may involve increasing the number of wiring layers used to dispose wiring lines that couple the first and second row decoder regions 121A and 121B and the slimming region SR. However, if the number of wiring layers is increased, then the number of process steps required for fabricating the memory device increases. As a consequence, fabrication time and cost may increase, and the probability that a defect occurs during fabrication processes may increase.

Referring back to FIG. 5, according to the disclosed embodiments, by disposing the slimming regions SR1, SR2 and SR3 on both sides of the first and second row decoder regions 121A and 121B and by distributing the wiring lines LWL to extend towards slimming regions on opposite sides of each of the first and second row decoder regions 121A and 121B, it is possible to prevent or reduce the wiring line bottleneck phenomenon. Accordingly, in disclosed embodiments, the wiring lines LWL do not need to be disposed in a top wiring layer and the number of the wiring layers to carry the wiring lines LWL does not need to increase. Therefore, it is possible to prevent an increase in the size of the memory device and to reduce the number of process steps required for fabricating the memory device.

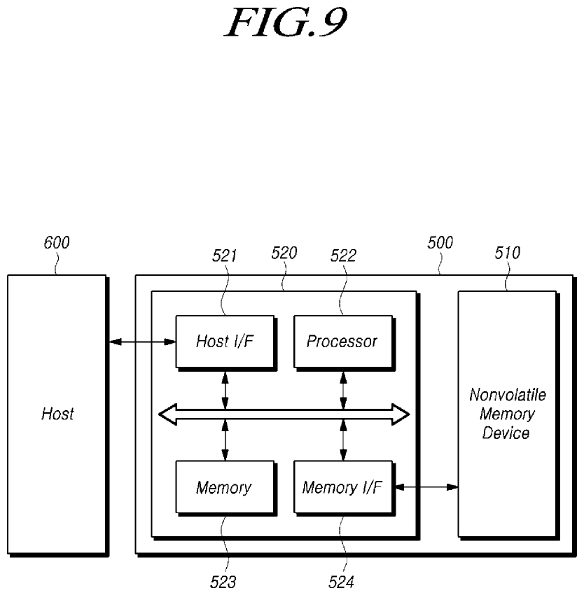

FIG. 9 is a block diagram schematically illustrating a memory system including a memory device in accordance with an embodiment of the present disclosure.

Referring to FIG. 9, a memory system 500 may store data to be accessed by a host 600 such as a mobile phone, an MP3 player, a laptop computer, a desktop computer, a game player, a TV, an in-vehicle infotainment system, and so forth.

The memory system 500 may be manufactured as any one of various kinds of storage devices according to the protocol of an interface, which is electrically coupled to the host 600. For example, the memory system 500 may be configured as any one of various kinds of storage devices such as a solid state drive, a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, a smart media card, a memory stick, and so forth.

The memory system 500 may be manufactured as any one among various kinds of package types. For example, the memory system 500 may be manufactured as any one of various kinds of package types such as a package-on-package (POP), a system-in-package (SIP), a system-on-chip (SOC), a multi-chip package (MCP), a chip-on-board (COB), a wafer-level fabricated package (WFP) and a wafer-level stack package (WSP).

The memory system 500 may include a nonvolatile memory device 510 and a controller 520.

The nonvolatile memory device 510 may operate as a storage medium of the memory system 500. The nonvolatile memory device 510 may be configured by any one of various types of nonvolatile memory devices, depending on the type of memory cells, such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase change random access memory (PRAM) using a chalcogenide alloy, and a resistive random access memory (RERAM) using a transition metal compound.

While FIG. 9 illustrates that the memory system 500 includes one nonvolatile memory device 510, this is only for the sake of convenience in explanation, and the memory system 500 may include a plurality of nonvolatile memory devices. The present disclosure may be applied the same to the memory system 500 including a plurality of nonvolatile memory devices. The nonvolatile memory device 510 may include the memory device according to embodiments of the present disclosure.

The controller 520 may control general operations of the memory system 500 through driving of firmware or software loaded in a memory 523. The controller 520 may decode and drive a code type instruction or algorithm such as firmware or software. The controller 520 may be implemented in the form of hardware or in a combined form of hardware and software.

The controller 520 may include a host interface Host I/F 521, a processor 522, the memory 523 and a memory interface Memory I/F 524. Although not illustrated in FIG. 9, the controller 520 may further include an ECC (error correction code) engine, which generates a parity by ECC-encoding write data provided from the host 600 and ECC-decodes read data, read from the nonvolatile memory device 510, by using the parity.

The host interface 521 may interface the host 600 and the memory system 500 in correspondence to the protocol of the host 600. For example, the host interface 521 may communicate with the host 600 through any one of universal serial bus (USB), universal flash storage (UFS), multimedia card (MMC), parallel advanced technology attachment (PATA), serial advanced technology attachment (SATA), small computer system interface (SCSI), serial attached SCSI (SAS), peripheral component interconnection (PCI) and PCI express (PCI-E) protocols.

The processor 522 may be configured by a micro control unit (MCU) or a central processing unit (CPU). The processor 522 may process a request transmitted from the host 600. In order to process a request transmitted from the host 600, the processor 522 may drive a code type instruction or algorithm, that is, firmware, loaded in the memory 523, and may control the internal function blocks such as the host interface 521, the memory 523 and the memory interface 524 and the nonvolatile memory device 510.

The processor 522 may generate control signals for controlling the operation of the nonvolatile memory device 510, on the basis of requests transmitted from the host 600, and may provide the generated control signals to the nonvolatile memory device 510 through the memory interface 524.

The memory 523 may be configured by a random access memory such as a dynamic random access memory (DRAM) or a static random access memory (SRAM). The memory 523 may store firmware to be driven by the processor 522. Also, the memory 523 may store data necessary for driving the firmware, for example, metadata. Namely, the memory 523 may operate as a working memory of the processor 522.

The memory 523 may be configured to include a data buffer for temporarily storing write data to be transmitted from the host 600 to the nonvolatile memory device 510 or read data to be transmitted from the nonvolatile memory device 510 to the host 600. In other words, the memory 523 may operate as a buffer memory. The memory 523 may receive and store map data from the nonvolatile memory device 510 when the memory system 500 is booted.

The memory interface 524 may control the nonvolatile memory device 510 under the control of the processor 522. The memory interface 524 may also be referred to as a memory controller. The memory interface 524 may provide control signals to the nonvolatile memory device 510. The control signals may include a command, an address, an operation control signal and so forth for controlling the nonvolatile memory device 510. The memory interface 524 may provide data, stored in the data buffer, to the nonvolatile memory device 510, or may store data, transmitted from the nonvolatile memory device 510, in the data buffer.

The controller 520 may further include a map cache (not illustrated) which caches map data referred to by the processor 522 among map data stored in the memory 523.

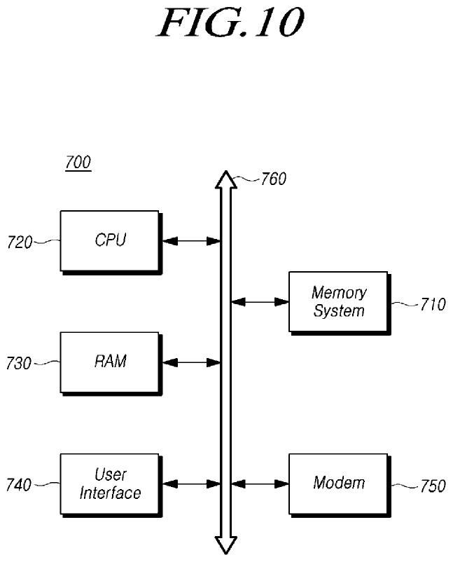

FIG. 10 is a block diagram schematically illustrating a computing system including a memory device in accordance with embodiments of the disclosure.

Referring to FIG. 10, a computing system 700 in accordance with an embodiment may include a memory system 710, a microprocessor (CPU) 720, a RAM 730, a user interface 740 and a modem 750 such as a baseband chipset, which are electrically coupled to a system bus 760. In the case where the computing system 700 in accordance with the embodiment is a mobile device, a battery (not shown) for supplying the operating voltage of the computing system 700 may be additionally provided. Although not shown in the drawing, it is obvious to a person skilled in the art to which the embodiment pertains that the computing system 700 in accordance with the embodiment may be additionally provided with an application chipset, a camera image processor (CIS), a mobile DRAM, and so on. The memory system 710 may configure, for example, an SSD (solid state drive/disk) which uses a nonvolatile memory to store data. Otherwise, the memory system 710 may be provided as a fusion flash memory (for example, a OneNAND flash memory).

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted by the appended claims and encompass all equivalents falling within the scope of the appended claims.

What is claimed is:

1. A memory device comprising:
a memory cell array included in a first semiconductor layer, and including a plurality of row lines that extend in a first direction, each of the plurality of row lines having a pad part disposed in a slimming region;
a row decoder included in a second semiconductor layer disposed under the first semiconductor layer, and overlapping the memory cell array in a vertical direction;
slimming regions disposed on both sides of the row decoder in the first direction; and
a plurality of wiring lines coupling the pad parts of the plurality of row lines and the row decoder.

2. The memory device according to claim 1, wherein the row decoder is divided into two row decoder regions, and the number of the slimming regions is three.

3. The memory device according to claim 1, wherein
the memory cell array is divided into a first memory region and a second memory region, each having a slimming region, and
each of the first memory region and the second memory region are disposed on both sides of one of the slimming regions in the first direction.

4. The memory device according to claim 1, further comprising:
a page buffer circuit configured in the second semiconductor layer, and overlapping the memory cell array in the vertical direction,
wherein the page buffer circuit is divided into a first page buffer region and a second page buffer region disposed on both sides, respectively, of any one of the slimming regions in the first direction when viewed from the top.

5. The memory device according to claim 4, wherein, from a top view, each of the first page buffer region and the second page buffer region intersects with a slimming region.

6. A memory device comprising:
a memory cell array including a plurality of interlayer dielectric layers and a plurality of electrode layers that are alternately stacked on a source plate;
a row decoder disposed on a substrate disposed under the source plate, and overlapping the memory cell array in a vertical direction; and
a plurality of wiring lines, configured in a bottom wiring layer between the substrate and the source plate, that couple pad parts of the plurality of electrode layers and the row decoder,
wherein when viewed from the top, some of the plurality of wiring lines are disposed in one side of the row decoder, and the other of the plurality of wiring lines are disposed in the other side of the row decoder.

7. The memory device according to claim 6, wherein
the row decoder is divided into a first row decoder region and a second row decoder region,
the first row decoder region is disposed between a first slimming region and a second slimming region,
the second row decoder region is disposed between the first slimming region and a third slimming region, and
the pad parts of the plurality of electrode layers are distributed among the first slimming region, the second slimming region and the third slimming region.

8. The memory device according to claim 7, wherein
the memory cell array is divided into a first memory region and a second memory region that are disposed on both sides of the first slimming region,
the second slimming region is configured in the first memory region, and
the third slimming region is configured in the second memory region.
